(19) United States
(12) Patent Application Publication
(10) Pub. No.: US 2022/0140797 A1
(43) Pub. Date: May 5, 2022

(54) BIDIRECTIONAL AMPLIFIER

(71) Applicant: NEC Corporation, Minato-ku, Tokyo (JP)

(72) Inventors: Naoki OSHIMA, Tokyo (JP); Kenichi OKADA, Tokyo (JP); Jian PANG, Tokyo (JP)

(73) Assignee: NEC Corporation, Minato-ku, Tokyo (JP)

(21) Appl. No.: 17/430,066

(22) PCT Filed: Dec. 16, 2019
(86) PCT No.: PCT/JP2019/049160

§ 371 Date: Aug. 11, 2021

(30) Foreign Application Priority Data
Feb. 14, 2019 (JP) 2019-024200

(51) Int. Cl. H03F 3/62; H03F 3/45

(52) U.S. Cl. CPC H03F 3/62; H03F 3/45183

(57) ABSTRACT

Provided is a bidirectional amplifier that can be downsized even when performance varies for each of a plurality of amplifying units. The bidirectional amplifier includes: a first amplifying unit configured to amplify a first signal input from a first terminal and output the amplified first signal from a second terminal; a second amplifying unit configured to amplify a second signal input from the second terminal, output the amplified second signal from the first terminal, and including a compensation element and a compensation element compensating for degradation in performance of the first amplifying unit; and a control unit configured to control an operation of the first amplifying unit and an operation of the second amplifying unit.

### TECHNICAL FIELD

The present disclosure relates to a bidirectional amplifier and particularly relates to a bidirectional amplifier that can be downsized even when performance varies for each of a plurality of amplifying units.

### BACKGROUND ART

Technologies for efficient use of a frequency band in wireless communication include a technology referred to as beam-forming performing wireless communication by using a directional radio wave. Methods of achieving the beam-forming includes a phased array. A phased array intensifies a radio wave in a desired direction by adjusting a phase of a wireless signal for each of a plurality of antenna elements and spatially combining the wireless signals (radio waves) radiated from the antenna elements. The plurality of antenna elements are desirably arranged at intervals of about a half wavelength of a carrier wave of a wireless signal, and the interval between antenna elements decreases as the frequency increases. In an integrated module in which an antenna and a high-frequency part of a transmitter-receiver are mounted on a single substrate, downsizing of the high-frequency part becomes necessary as the interval between the antenna elements is decreased. Since the high-frequency part includes a transmission amplifier and a reception amplifier, downsizing of the amplifiers is desired. Methods of the downsizing include use of a bidirectional amplifier serving as a transmission amplifier and a reception amplifier.

Patent Literature 1 discloses a wireless communication device including: a transmission final stage circuit including a first differential amplifying circuit including transistors Q11 and Q12, the bases of the transistors being connected to terminals 3A and 3B and the collectors of the transistors being connected to terminals 1A and 1B, respectively, and a first constant current source including transistors Q13 and Q14 supplying operating current of the differential amplifying circuit by a signal C5; and a reception front-end circuit including a second differential amplifying circuit including transistors Q21 and Q22, the bases of the transistors being connected to terminals 1A and 1B and the collector of the transistors being connected to terminals 2A and 2B, respectively, and a second constant current source including transistors Q23 and Q24 supplying operating current of the second differential amplifying circuit by a signal C4 complementary to the signal C5, wherein switching between transmission and reception is made by operation-nonoperation of the first differential amplifying circuit and the second actuating amplifying circuit controlled by the signals C4 and C5. The technology disclosed in Patent Literature 1 requires an external switch for switching between transmission and reception, in addition to the first differential amplifying circuit and the second differential amplifying circuit; and therefore it is difficult to provide a downsized bidirectional amplifier (wireless communication device).

### CITATION LIST

### Patent Literature

Patent Literature 1: Japanese Unexamined Patent Application Publication No. H8-149038

### SUMMARY OF INVENTION

### Technical Problem

As described above, there is a problem that it is difficult to downsize a bidirectional amplifier performing transmission and reception.

An object of the present disclosure is to provide a bidirectional amplifier solving the aforementioned problem.

### Solution to Problem

A bidirectional amplifier according to the present disclosure includes:

a first amplifying unit configured to amplify a first signal input from a first terminal and output the amplified first signal from a second terminal;

a second amplifying unit configured to amplify a second signal input from the second terminal, output the amplified second signal from the first terminal, and including a compensation element compensating for degradation in performance of the first amplifying unit; and

a control unit configured to control an operation of the first amplifying unit and an operation of the second amplifying unit.

### Advantageous Effects of Invention

The present disclosure can provide a bidirectional amplifier that can be downsized even when performance varies for each of a plurality of amplifying units.

### BRIEF DESCRIPTION OF DRAWINGS

FIG. 1 is a block diagram illustrating a bidirectional amplifier according to a first example embodiment.

FIG. 2 is a circuit diagram illustrating the bidirectional amplifier according to the first example embodiment.

FIG. 3 is a circuit diagram illustrating a bidirectional amplifier according to a comparative example of the first example embodiment.

FIG. 4 is a circuit diagram illustrating a bidirectional amplifier according to a second example embodiment.

FIG. 5 is a circuit diagram illustrating a bidirectional amplifier according to a third example embodiment.

### DESCRIPTION OF EMBODIMENTS

Example embodiments of the present invention will be described below with reference to drawings. In each drawing, the same or corresponding components are given the same signs, and redundant description thereof is omitted as needed for clarification of description.

### First Example Embodiment

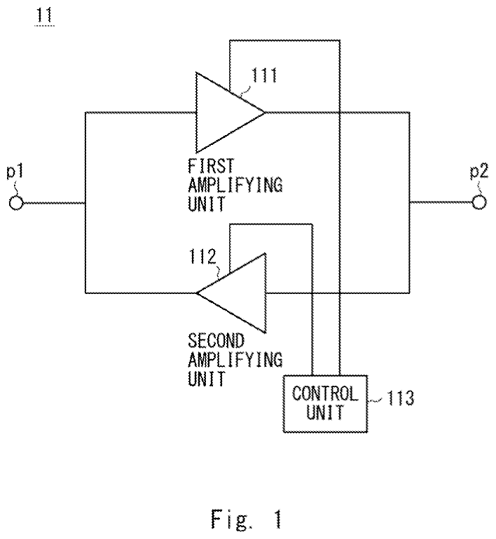

First, an outline of a bidirectional amplifier according to a first example embodiment will be described. FIG. 1 is a block diagram illustrating the bidirectional amplifier according to the first example embodiment.

As illustrated in FIG. 1, a bidirectional amplifier 11 according to the first example embodiment includes a first amplifying unit 111, a second amplifying unit 112, and a control unit 113. The first amplifying unit 111 and the second amplifying unit 112 may also be collectively referred to as amplifying units.

The first amplifying unit 111 amplifies a first signal input from a first terminal p1 and outputs the amplified first signal from a second terminal p2.

The second amplifying unit 112 amplifies a second signal input from the second terminal p2 and outputs the amplified second signal from the first terminal p1. Further, the second amplifying unit 112 includes a compensation element (unillustrated) compensating for degradation in performance of the first amplifying unit 111. Details of degradation in performance of the first amplifying unit 111 and the compensation element for compensating for the degradation will be described later.

The control unit 113 controls an operation of the first amplifying unit 111 and an operation of the second amplifying unit 112. For example, since the first amplifying unit 111 is used as an amplifier for transmission and the second amplifying unit 112 is used as an amplifier for reception, the bidirectional amplifier 11 is configured in such a way that performance of the first amplifying unit 111 differs from performance of the second amplifying unit 112. For example, performance herein refers to a transmission output value and a noise figure of an amplifying unit.

Specifically, a large-sized transistor is used in the first amplifying unit 111, and a transistor sized smaller than that used in the first amplifying unit 111 is used in the second amplifying unit 112. A large-sized transistor has high output and therefore is suitable for a power amplifier (PA) for transmission. A small-sized transistor is low-noise and therefore is suitable for a low noise amplifier (LNA) for reception.

Thus, the first amplifying unit 111 is operated as a PA for transmission and the second amplifying unit 112 is operated as an LNA for reception in such a way that performance varies for each of the two amplifying units. In other words, performance varies for each of the amplifying units by using differently sized transistors as transistors in the amplifying units. A PA may be referred to as a transmission amplifier, and an LNA may be referred to as a reception amplifier.

At this time, the first amplifying unit 111 operates as a PA and the second amplifying unit 112 operates as an LNA in the bidirectional amplifier 11, and therefore the transmission output value of the first amplifying unit 111 is greater than the transmission output value of the second amplifying unit 112. Further, the noise figure of the second amplifying unit 112 is less than the noise figure of the first amplifying unit 111.

Further, when the PA (first amplifying unit 111) and the LNA (second amplifying unit 112) are mounted on a single substrate in order to downsize the bidirectional amplifier 11, performance of the first amplifying unit 111 is degraded due to use of differently sized transistors. The bidirectional amplifier 11 includes a compensation element for compensating for degradation in performance of the first amplifying unit 111 and therefore can suppress the degradation in performance. Thus, a bidirectional amplifier 11 that can be downsized can be provided even when the first amplifying unit 111 is operated as a PA and the second amplifying unit 112 is operated as an LNA, in other words, when performance varies for each of a plurality of amplifying units.

Further, the control unit 113 performs control in such a way that the second amplifying unit 112 does not operate while the first amplifying unit 111 is in operation and the first amplifying unit 111 does not operate while the second amplifying unit 112 is in operation.

Thus, even when a first output signal output from the first amplifying unit 111 sneaks into the second amplifying unit 112, the first output signal is not amplified since the second amplifying unit 112 is not in operation. Further, even when a second output signal output from the second amplifying unit 112 sneaks into the first amplifying unit 111, the second output signal is not amplified since the first amplifying unit 111 is not in operation. Accordingly, an adverse effect caused by sneaking can be reduced.

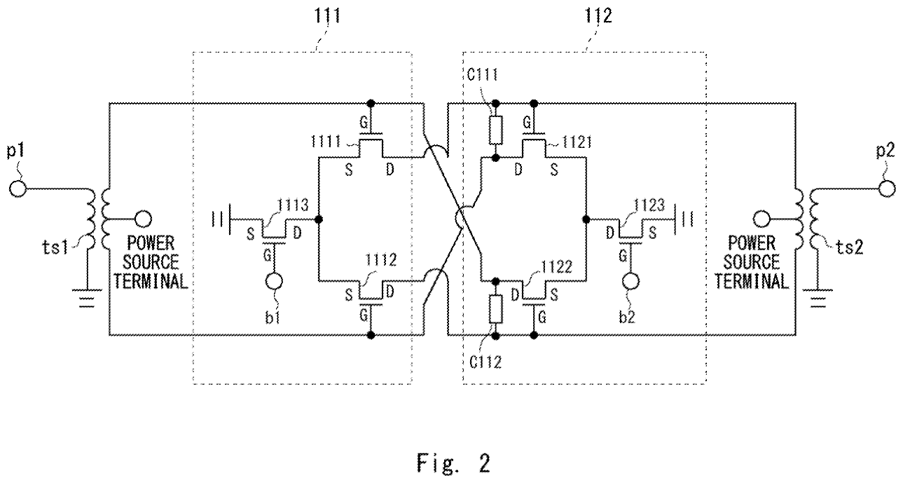

Next, details of the bidirectional amplifier according to the first example embodiment will be described. FIG. 2 is a circuit diagram illustrating the bidirectional amplifier according to the first example embodiment. Note that the control unit 113 is omitted for simplification.

As illustrated in FIG. 2, the first amplifying unit 111 in the bidirectional amplifier 11 includes a transistor 1111, a transistor 1112, and a transistor 1113. Two transistors being the transistor 1111 and the transistor 1112 amplify the first signal. The size of the transistor 1111 and the size of the transistor 1112 are the same.

The first amplifying unit 111 includes the transistor 1113 between the source S of the transistor 1111 and a ground GND. The transistor 1113 controls operations of the transistor 1111 and the transistor 1112.

The second amplifying unit 112 includes a transistor 1121, a transistor 1122, a transistor 1123, a compensation element C111, and a compensation element C112. Two transistors being the transistor 1121 and the transistor 1122 amplify the second signal. The size of the transistor 1121 and the size of the transistor 1122 are the same.

The second amplifying unit 112 includes the compensation element C111 between the gate G and the drain D of the transistor 1121 and includes the compensation element C112 between the gate G and the drain D of the transistor 1122. The compensation element C111 and the compensation element C112 compensate for parasitic components of the transistor 1111 and the transistor 1112. Each of the compensation element C111 and the compensation element C112 is a capacitor or a variable capacitor.

The second amplifying unit 112 includes the transistor 1123 between the source S of the transistor 1121 and the ground GND. The transistor 1123 controls operations of the transistor 1121 and the transistor 1122.

The size of the transistor 1111 is larger than the size of the transistor 1121 and the transistor 1122. Further, the size of the transistor 1112 is larger than the size of the transistor 1121 and the transistor 1122.

Thus, the first amplifying unit 111 can be operated as a transmission amplifier, and the second amplifying unit 112 can be operated as a reception amplifier.

By controlling the transistor 1113 through a first bias terminal b1, the control unit 113 performs on-off control of the transistor 1111 and the transistor 1112. Further, by controlling the transistor 1123 through a second bias terminal b2, the control unit 113 performs on-off control of the transistor 1121 and the transistor 1122.

Then, the control unit 113 causes the second amplifying unit 112 not to operate (the transistor 1121 and the transistor 1122 are turned off) while the first amplifying unit 111 is in operation (the transistor 1111 and the transistor 1112 are turned on). The control unit 113 causes the first amplifying unit 111 not to operate (the transistor 1111 and the transistor 1112 are turned off) while the second amplifying unit 112 is in operation (the transistor 1121 and the transistor 1122 are turned on).

Since the bidirectional amplifier 11 uses the transistor 1113 and the transistor 1123 for on-off control of the first amplifying unit 111 and the second amplifying unit 112, the circuit area can be reduced compared with a case of performing control using an inductor.

Since the transistor 1111 and the transistor 1112 operate differentially, the transistors may also be referred to as first differential transistors. Further, since the transistor 1121 and the transistor 1122 operate differentially, the transistors may also be referred to as second differential transistors.

The compensation element C111 and the compensation element C112 are used for canceling out parasitic components of the transistor 1111 and the transistor 1112.

Next, an operation of the bidirectional amplifier according to the first example embodiment will be described.

As illustrated in FIG. 2, the first signal input from the first terminal p1 undergoes differential-single conversion by a first transformer ts1. The first transformer ts1 also serves as a load of the first amplifying unit 111. On the other hand, the second signal input from the second terminal p2 undergoes differential-single conversion by a second transformer ts2. The second transformer ts2 also serves as a load of the second amplifying unit 112.

A case of the control unit 113 controlling the transistor 1113 to be turned on through the first bias terminal b1 and controlling the transistor 1123 to be turned off through the second bias terminal b2 will be described.

At this time, the transistor 1111 and the transistor 1112 are turned on, and the transistor 1121 and the transistor 1122 are turned off. Thus, the first signal input from the first terminal p1 is amplified by the transistor 1111 and the transistor 1112 and is output from the second terminal p2.

A degradation factor in performance of a high-frequency amplifier is a parasitic component caused by wiring and the like. When a source-grounded type transistor in particular is used, a degradation factor in performance of a high-frequency amplifier is a parasitic component (parasitic capacitance) between the gate and the drain of a transistor. Therefore, by inserting an equivalent capacitor to be cross coupled between a differential input and a differential output, the parasitic component can be canceled out.

Parasitic components of the transistor 1111 and the transistor 1112 degrades performance of the first amplifying unit 111 in the bidirectional amplifier 11. Therefore, the parasitic components of the transistor 1111 and the transistor 1112 are compensated for by using parasitic components of the transistor 1121 and the transistor 1122 in an off-state. However, since the size of the transistor 1111 and the transistor 1112 is different from the size of the transistor 1121 and the transistor 1122, the parasitic components of the transistor 1111 and the transistor 1112 cannot be completely canceled out (compensated for) even when cross coupling is provided between the differential input and the differential output.

Then, the bidirectional amplifier 11 compensates for the shortfall by using the compensation element C111 and the compensation element C112. Specifically, the compensation element C111 is provided between the gate G and the drain D of the transistor 1121, and the compensation element C112 is provided between the gate G and the drain D of the transistor 1122. Thus, the parasitic components of the transistor 1111 and the transistor 1112 are canceled out by the total of the parasitic components of the transistor 1111 and the transistor 1122, the compensation element C111, and the compensation element C112.

The same applies to a case of the control unit 113 controlling the transistor 1113 to be turned off through the first bias terminal b1 and controlling the transistor 1123 to be turned on through the second bias terminal b2. Specifically, the total of the parasitic components of the transistor 1121 and the transistor 1122, the compensation element C111, and the compensation element C112 is canceled out by the parasitic components of the transistor 1111 and the transistor 1112.

Thus, the first example embodiment enables compensation for parasitic components even when differently sized transistors are used in bidirectional amplification and thus can provide a high-performance amplifier.

Further, a switch such as a large-area inductor element is not required for switching between transmission and reception, and therefore a bidirectional amplifier that can be downsized can be provided even when performance varies for each of amplifying units.

Further, the bidirectional amplifier 11 does not require a switch for switching between transmission and reception and therefore does not have a related passing loss. Therefore, reduction in a gain of an amplifying unit, reduction in a transmission output, and degradation in noise characteristic at reception can be suppressed compared with a case of a switch being required.

Further, variations in the first amplifying unit 111 and the second amplifying unit 112 in the bidirectional amplifier 11 can be compensated for by the compensation element C111 and the compensation element C112.

Characteristics of the bidirectional amplifier 11 according to the first example embodiment will be described.

The size of the transistors operating in a forward direction (a direction from the first terminal p1 toward the second terminal p2) is different from the size of the transistors operating in a backward direction (a direction from the second terminal p2 toward the first terminal p1).

Each of the first amplifying unit 111 and the second amplifying unit 112 has a differential configuration and has the cross coupled compensation element C111 and compensation element C112 between the differentials.

### COMPARATIVE EXAMPLE

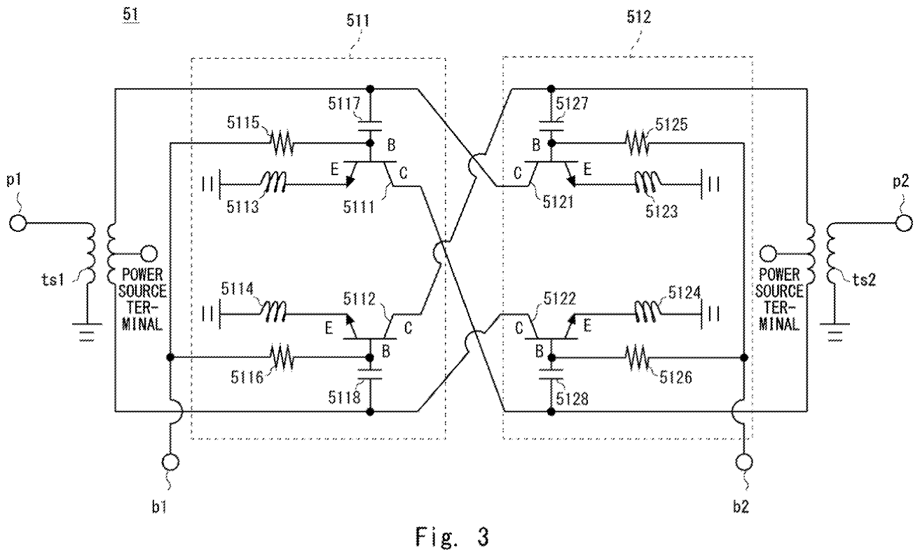

FIG. 3 is a circuit diagram illustrating a bidirectional amplifier according to a comparative example of the first example embodiment.

As illustrated in FIG. 3, a bidirectional amplifier 51 according to the comparative example controls an input-output direction by controlling each of a first bias terminal b1 and a second bias terminal b2. When the bidirectional amplifier 51 controls a transistor 5111 and a transistor 5112 to be turned on and controls a transistor 5121 and a transistor 5122 to be turned off, a first signal is transmitted in a direction from a first terminal p1 to a second terminal p2. When the bidirectional amplifier 51 controls the transistor 5111 and the transistor 5112 to be turned off and controls the transistor 5121 and the transistor 5122 to be turned on, a second signal is transmitted in a direction from the second terminal p2 to the first terminal p1.

In the bidirectional amplifier 51, the collector C of the transistor 5111 is connected to the base B of the transistor 5122, and the base B of the transistor 5111 is connected to the collector C of the transistor 5121. Further, the collector C of the transistor 5112 is connected to the base B of the transistor 5121, and the base B of the transistor 5112 is connected to the collector C of the transistor 5122. Thus, parasitic capacitance can be canceled out.

When the first bias terminal b1 of the bidirectional amplifier 51 is set to High and the second bias terminal b2 is set to Low, the transistor 5111 and the transistor 5112 are turned on, and the transistor 5121 and the transistor 5122 are turned off.

Consequently, the first signal input from the first terminal p1 is amplified and is output from the second terminal p2. At this time, an inductor 5113, an inductor 5114, an inductor 5123, and an inductor 5124 provide matching between a first amplifying unit 511 and a second amplifying unit 512 and at the same time enhance isolation when the transistor 5111, the transistor 5112, the transistor 5121, and the transistor 5122 are in off-operation.

Further, at this time, parasitic capacitance between the base B and the collector C of the transistor 5121 in the off-state is canceled out by parasitic capacitance between the base B and the collector C of the transistor 5111. Parasitic capacitance between the base B and the collector C of the transistor 5122 in the off-state is canceled out by parasitic capacitance between the base B and the collector C of the transistor 5112. An operation in a case of the first bias terminal b1 being set to Low and the second bias terminal b2 being set to High is similar to the above.

Note that, as a condition for the operations to be effective, parasitic capacitance of the first amplifying unit 511 needs to be equal to that of the second amplifying unit 512, in other words, every characteristic value of the same element type in the first amplifying unit 511 and the second amplifying unit 512 needs to be the same and a layout configuration (structure) and the like need to be symmetric.

Accordingly, it is difficult to cancel out parasitic capacitance of transistors when the transistors used in the first amplifying unit 511 and the transistors used in the second amplifying unit 512 have different sizes. Consequently, when performance varies for each of a plurality of amplifying units, it is difficult to downsize the bidirectional amplifier in the comparative example.

### Second Example Embodiment

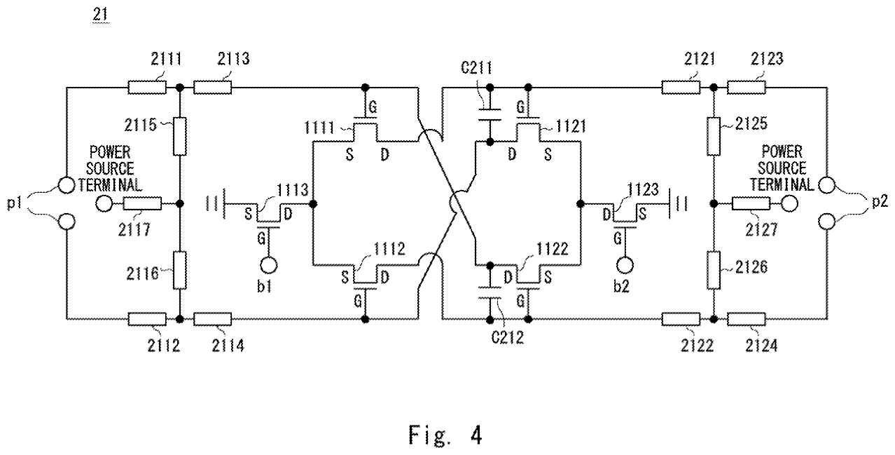

FIG. 4 is a circuit diagram illustrating a bidirectional amplifier according to a second example embodiment.

As illustrated in FIG. 4, the bidirectional amplifier 21 according to the second example embodiment differs from the bidirectional amplifier 11 according to the first example embodiment in that a transmission line 2111 to a transmission line 2117 are provided between a first terminal p1 and a first amplifying unit 111. Further, the bidirectional amplifier 21 differs in that a transmission line 2121 to a transmission line 2127 are provided between a second terminal p2 and a second amplifying unit 112. Further, the bidirectional amplifier 21 differs in that a capacitor C211 and a capacitor C212 are provided in place of the compensation element C111 and the compensation element C112.

By using a capacitor as a compensation element, the bidirectional amplifier 21 can be downsized even when performance varies for each of a plurality of amplifying units.

Further, the bidirectional amplifier 21 may form a first matching circuit on the first terminal p1 side with the transmission line 2111 to the transmission line 2117. Further, the bidirectional amplifier 21 may form a second matching circuit on the second terminal p2 side with the transmission line 2121 to the transmission line 2127.

Thus, the bidirectional amplifier 21 can include matching circuits shared between a forward direction and a backward direction. The first matching circuit and the second matching circuit may be applied to the bidirectional amplifier 11 according to the first example embodiment.

### Third Example Embodiment

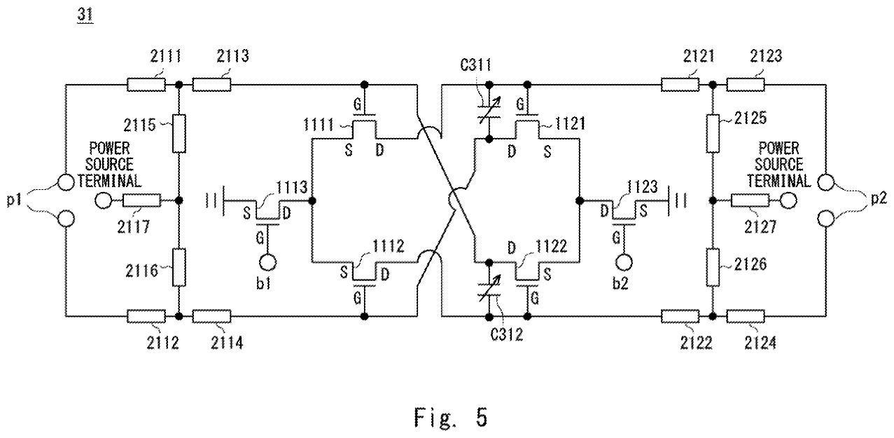

FIG. 5 is a circuit diagram illustrating a bidirectional amplifier according to a third example embodiment.

As illustrated in FIG. 5, the bidirectional amplifier 31 according to the third example embodiment differs from the bidirectional amplifier 21 according to the second example embodiment in that a variable capacitor C311 and a variable capacitor C312 are provided in place of the capacitor C211 and the capacitor C212.

By using a variable capacitor as a compensation element, the bidirectional amplifier 31 can be downsized even when performance varies for each of a plurality of amplifying units.

The example embodiments have been described with a bidirectional amplifier as an example but are not limited thereto. The example embodiments are applicable to not only a bidirectional amplifier but also components required for a transmitter-receiver, such as a phase shifter and a filter.

The present disclosure is not limited to the aforementioned example embodiments and may be modified as appropriate without departing from the spirit of the present disclosure.

While the present invention has been described above with reference to the example embodiments, the present invention is not limited to the aforementioned example embodiments. Various changes and modifications that may be understood by a person skilled in the art may be made to the configurations and details of the present invention within the scope of the present invention.

This application is based upon and claims the benefit of priority from Japanese Patent Application No. 2019-024200, filed on Feb. 14, 2019, the disclosure of which is incorporated herein in its entirety by reference.

### REFERENCE SIGNS LIST

11, 51 BIDIRECTIONAL AMPLIFIER
111, 511 FIRST AMPLIFYING UNIT
1111, 1112, 1113 TRANSISTOR
112, 512 SECOND AMPLIFYING UNIT
1121, 1122, 1123 TRANSISTOR
C111, C112 COMPENSATION ELEMENT
C211, C212 CAPACITOR
2111 to 2117, 2121 to 2127 TRANSMISSION LINE
C311, C312 VARIABLE CAPACITOR
5113, 5114, 5123, 5124 INDUCTOR
113 CONTROL UNIT
p1 FIRST TERMINAL
p2 SECOND TERMINAL
b1 FIRST BIAS TERMINAL
b2 SECOND BIAS TERMINAL
S SOURCE
G GATE
D DRAIN
B BASE
C COLLECTOR
ts1 FIRST TRANSFORMER
ts2 SECOND TRANSFORMER
GND GROUND

What is claimed is:

1. A bidirectional amplifier comprising:
first amplifying unit that amplifies a first signal input from a first terminal and outputs the amplified first signal from a second terminal;
second amplifying unit that amplifies a second signal input from the second terminal, outputs the amplified second signal from the first terminal, and includes a compensation element compensating for degradation in performance of the first amplifying unit; and
control unit that controls an operation of the first amplifying unit and an operation of the second amplifying unit.

2. The bidirectional amplifier according to claim 1, wherein the control unit performs control in such a way that
the second amplifying unit does not operate while the first amplifying unit in operation, and
the first amplifying unit does not operate while the second amplifying unit is in operation.

3. The bidirectional amplifier according to claim 1, wherein performance of the first amplifying unit is different from performance of the second amplifying unit.

4. The bidirectional amplifier according to claim 1, wherein the performance includes a transmission output value and a noise figure.

5. The bidirectional amplifier according to claim 4, wherein
the transmission output value of the first amplifying unit is greater than the transmission output value of the second amplifying unit, and
the noise figure of the second amplifying unit is less than the noise figure of the first amplifying unit.

6. The bidirectional amplifier according to claim 1, wherein
the first amplifying unit includes two first differential transistors amplifying the first signal,
the second amplifying unit includes two second differential transistors amplifying the second signal, and
a size of the first differential transistor is larger than a size of the second differential transistor.

7. The bidirectional amplifier according to claim 6, wherein
the first amplifying unit includes, between a source of the first differential transistor and a ground, a first bias transistor controlling an operation of the first differential transistor, and
the second amplifying unit
includes, between a gate and a drain of the second differential transistor, the compensation element compensating for a parasitic component of the first differential transistor, and
includes, between a source of the second differential transistor and a ground, a second bias transistor controlling an operation of the second differential transistor.

8. The bidirectional amplifier according to claim 1, wherein the compensation element is a capacitor or a variable capacitor.

9. The bidirectional amplifier according to claim 1, wherein
the first amplifying unit includes a first matching circuit between the first terminal and the first amplifying unit, and
the second amplifying unit includes a second matching circuit between the second terminal and the second amplifying unit.
